(19) United States
(12) Patent Application Publication
(10) Pub. No.: US 2020/0168987 A1
(43) Pub. Date: May 28, 2020

(54) Neutralization of Environmental Influences on the Transmitting Parameters

(71) Applicants: Fraunhofer-Gesellschaft zur Foerderung der angewandten Forschung e.V., Munich (DE); Diehl Metering GmbH, Ansbach (DE)

(72) Inventors: Gerd KILIAN, Erlangen (DE); Josef BERNHARD, Erlangen (DE); Johannes WECHSLER, Erlangen (DE); Jakob KNEISSL, Erlangen (DE); Dominik SOLLER, Erlangen (DE); Michael SCHLICHT, Erlangen (DE); Thomas KAUPPERT, Nuernberg (DE); Hristo PETKOV, Nuernberg (DE); Raphael MZYK, Kammerstein (DE); Klaus GOTTSCHALK, Winkelhaid (DE)

(21) Appl. No.: 16/691,090

(22) Filed: Nov. 21, 2019

(30) Foreign Application Priority Data
Nov. 23, 2018 (DE) 10 2018 220 202.8

(51) Int. Cl. H01Q 1/42; H04B 15/02; H05K 9/00; H04B 1/04; H03B 1/04; H04L 7/00; H04B 1/036

(52) U.S. Cl. CPC H01Q 1/42; H04B 15/02; H05K 9/0081; H03B 2202/04; H03B 1/04; H04L 7/0016; H04B 1/036; H04B 1/0475

(57) ABSTRACT

Embodiments provide a data transmitter having a transmitter configured to transmit a signal, wherein at least one signal parameter of the signal depends on an environmental parameter in an environment of the data transmitter, and a shielding unit configured to shield the transmitter or part of the transmitter from the environmental parameter to reduce a receiver-side reconstructable effect of the environmental parameter on the at least one signal parameter and/or a modifier for modifying the signal parameter configured to modify the at least one signal parameter to reduce a receiver-side reconstructable effect of the environmental parameter on the at least one signal parameter, wherein the modifier for modifying the signal parameter is configured to modify the at least one signal parameter directly or a signal derived from a clock signal of a clock generator of the data transmitter on which the signal or generation of the signal depends, in order to modify the at least one signal parameter.

### CROSS-REFERENCE TO RELATED APPLICATIONS

This application claims priority from German Patent Application No. 10 2018 220 202.8, which was filed on Nov. 23, 2018, and is incorporated herein in its entirety by reference.

Embodiments of the present invention relate to a data transmitter, a data receiver as well as a communication system having a data transmitter and a data receiver and, in particular, to a reduction of environmental influences (environmental parameters) on signals transmitted in the communication system.

### BACKGROUND OF THE INVENTION

Conventionally, clock generators, such as oscillators, are used in radio systems for generating signals. Clock signals provided by the clock generators and, hence, also the transmitting signals derived from the clock signals depend, however, on the environmental conditions (environmental parameters), in particular a temperature, in the respective environments of the data transmitters.

Thus, by evaluating signal parameters of the received signals, it is possible to draw conclusions on the environmental conditions of the respective data transmitters.

### SUMMARY

According to an embodiment, a data transmitter may have: transmitting means configured to transmit a signal, wherein at least one signal parameter of the signal depends on an environmental parameter in an environment of the data transmitter, and shielding means configured to shield the transmitting means or part of the transmitting means from the environmental parameter to reduce a receiver-side reconstructable effect of the environmental parameter on the at least one signal parameter.

According to another embodiment, a data transmitter may have: transmitting means configured to transmit a signal, wherein at least one signal parameter of the signal depends on an environmental parameter in an environment of the data transmitter and means for modifying the signal parameter configured to modify the at least one signal parameter to reduce a receiver-side reconstructable effect of the environmental parameter on the at least one signal parameter, wherein the means for modifying the signal parameter is configured to modify the at least one signal parameter directly or a signal derived from a clock signal of a clock generator of the data transmitter on which the signal or generation of the signal depends, in order to modify the signal parameter.

Another embodiment may have a data receiver, wherein the data receiver is configured to receive a signal of a data transmitter, wherein the signal or a generation of the signal depends on a clock signal of a clock generator of the data transmitter, wherein the data receiver is configured to determine a signal parameter of the signal and to determine, based on the signal parameter, an environmental parameter to which the clock generator of the data transmitter or the signal is exposed, wherein the data transmitter is configured to compensate a data transmitter-side modification of the signal parameter prior to the estimation of the signal parameter or the environmental parameter.

According to another embodiment, a system may have: an inventive data transmitter and an inventive data receiver.

According to another embodiment, a method may have the steps of: transmitting a signal with transmitting means of the data transmitter, wherein at least one signal parameter of the signal depends on an environmental parameter in an environment of the data transmitter, shielding the transmitting means or part of the transmitting means from the environmental parameter to reduce a receiver-side reconstructable effect of the environmental parameter on the at least one signal parameter.

According to another embodiment, a method for operating a data transmitter may have the steps of: generating a transmitting signal, wherein at least one signal parameter of the transmitting signal depends on an environmental parameter in an environment of the data transmitter, wherein, when generating the transmitting signal, the at least one signal parameter is modified to reduce a receiver-side reconstructable effect of the environmental parameter on the at least one signal parameter, wherein the signal parameter directly or a signal derived from a clock signal of a clock generator of the data transmitter on which the signal or generation of the signal depends is modified in order to modify the signal parameter and transmitting the transmitting signal.

According to another embodiment, a method may have the steps of: receiving a signal of a data transmitter, wherein the signal or a generation of the signal depends on a clock signal of a clock generator of the data transmitter, determining a signal parameter of the received signal, determining, based on the determined signal parameter, an environmental parameter to which the clock generator of the data transmitter or the signal is exposed, and compensating a data transmitter-side modification of the signal parameter prior to determining the signal parameter or the environmental parameter.

Another embodiment may have a non-transitory digital storage medium having a computer program stored thereon to perform any of the inventive methods when said computer program is run by a computer.

Embodiments provide a data transmitter having transmitting means configured to transmit a signal, wherein at least one signal parameter of the signal depends on an environmental parameter in an environment of the data transmitter, and shielding means configured to shield the transmitting means or part of the transmitting means from the environmental parameter to reduce a receiver-side reconstructable effect of the environmental parameter on the at least one signal parameter (e.g. to obstruct a receiver-side estimation of the environmental parameter based on the at least one signal parameter).

In embodiments, the transmitting means can comprise a clock generator, wherein a clock signal (e.g. a clock signal parameter (e.g. clock frequency) of the clock signal) provided by the clock generator depends on the environmental parameter in the environment of the data transmitter, wherein the signal or a generation of the signal depends on the clock signal of the clock generator, wherein the shielding means is configured to shield the transmitting means or the clock generator of the transmitting means from the environmental parameter (e.g. to reduce an influence of the environmental parameter on a clock signal parameter of the clock signal).

In embodiments, the environmental parameter can be an ambient temperature, wherein the shielding means is configured to thermally shield the transmitting means from the ambient temperature.

In embodiments, the environmental parameter can be an ambient temperature, wherein the shielding means is configured to increase thermal inertia between the ambient temperature and the transmitting means (e.g. to increase thermal inertia between the ambient temperature and an effect of the ambient temperature on the signal parameter).

In embodiments, the shielding means can comprise a cooling body thermally coupled to the transmitting means (e.g. to increase thermal stability and/or inertia).

In embodiments, the shielding means can be configured to cool the transmitting means.

The shielding means can comprise, for example, a cooling body that is configured to cool the transmitting means in order to increase, e.g., thermal stability and/or inertia.

In embodiments, the shielding means can be configured to heat the transmitting means.

For example, the shielding means can comprise a heating element that is configured to heat the transmitting means, e.g. to increase thermal stability and/or inertia.

In embodiments, the shielding means can be configured to thermally couple the transmitting means or a clock generator of the transmitting means to a microcontroller of the data transmitter in order to influence a temperature of the transmitting means or the clock generator.

For example, computation-intensive computing steps can be performed on the microcontroller in order to increase the temperature of the transmitting means.

In embodiments, the data transmitter can be configured to activate the microcontroller at random or pseudo-random times to influence a temperature of the transmitting means or the clock generator.

In embodiments, the data transmitter can be configured to leave the microcontroller activated for a random or pseudo-random time to influence a temperature of the transmitting means or the clock generator.

In embodiments, the shielding means can be configured to reduce the influence of the environmental parameter on the signal parameter by at least the factor 5 [e.g. or 10].

In embodiments, the signal parameter of the signal can be
a carrier frequency
a transmitting time
a symbol rate
a modulation index or
a signal power
   or a change of the same.

In embodiments, the environmental parameter can be
a temperature
a humidity
an atmospheric pressure
an electromagnetic radiation
a brightness
a movement and/or
a vibration
   or a change of the same.

In embodiments, the data transmitter can comprise means for modifying the signal parameter configured to modify the at least one signal parameter to reduce a receiver-side reconstructable effect of the environmental parameter on the at least one signal parameter (e.g. to obstruct a receiver-side estimation of the environmental parameter based on the at least one signal parameter), wherein the means for modifying the signal parameter is configured to modify the at least one signal parameter directly or a signal derived from a clock signal of a clock generator of the data transmitter on which the signal or a generation of the signal depends, in order to modify the at least one signal parameter.

Further embodiments provide a data transmitter, wherein the data transmitter comprises transmitting means configured to transmit a signal, wherein at least one signal parameter of the signal depends on an environmental parameter in an environment of the data transmitter, wherein the data transmitter comprises means for modifying the signal parameter configured to modify at least one signal parameter to reduce a receiver-side reconstructable effect of the environmental parameter on the at least one signal parameter (e.g. to obstruct a receiver-side estimation of the environmental parameter based on the at least one signal parameter), wherein the means for modifying the signal parameter is configured to modify the at least one signal parameter directly or a signal derived from a clock signal of a clock generator of the data transmitter on which the signal or a generation of the signal depends, in order to modify the signal parameter.

In embodiments, the means for modifying the signal parameter can be configured to modify the signal parameter based on a deviation of the signal parameter from a set value.

In embodiments, a clock signal provided by the clock generator can depend on the environmental parameter in the environment of the data transmitter, wherein the signal or a generation of the signal depends on the clock signal of the clock generator.

In embodiments, the means for modifying the signal parameter can be configured to determine a deviation of a clock signal parameter (e.g. frequency) of the clock signal from a set value (e.g. set frequency), wherein the means for modifying the signal parameter is configured to modify the signal parameter of the signal based on the determined deviation of the clock signal parameter.

In embodiments, the means for modifying the signal parameter can be configured to modify the signal parameter of the signal in dependence on the environmental parameter in the environment of the data transmitter.

In embodiments, the data transmitter can be configured to determine the environmental parameter in the environment of the data transmitter.

The data transmitter can comprise, for example, a sensor for the environmental parameter.

In embodiments, the data transmitter can be configured to receive a signal from a different data transmitter, wherein the received signal comprises information on the environmental parameter in the environment of the data transmitter or wherein the data transmitter is configured to estimate the environmental parameter in the environment of the data transmitter based on a signal parameter of the received signal.

In embodiments, the means for modifying the signal parameter can be configured to change a clock divider of the clock signal used for generating the signal based on the environmental parameter in the environment of the data transmitter in order to modify the signal parameter of the signal, wherein the clock divider is not part of the clock generator.

In embodiments, the means for modifying the signal parameter can be configured to adjust an adjustable capacitor used for generating the signal based on the environmental parameter in the environment of the data transmitter to modify the signal parameter of the signal, wherein the capacitor is not part of the clock generator.

In embodiments, the means for modifying the signal parameter can be configured to output correction values for the signal parameter to the transmitting means to modify the signal parameter of the signal.

In embodiments, the signal parameter of the signal can be
a carrier frequency
a transmitting time
a symbol rate
a modulation index or
a signal power
   or a change of the same.

In embodiments, the environmental parameter can be
a temperature
a humidity
an atmospheric pressure
an electromagnetic radiation
a brightness
a movement and/or
a vibration
   or a change of the same.

In embodiments, the data transmitter can be configured to receive a signal of a data transmitter, wherein the signal or a generation of the signal depends on a clock signal of a clock generator of the data transmitter, wherein the data receiver is configured to determine a signal parameter of the signal and to determine, based on the signal parameter, an environmental parameter to which the clock generator of the data transmitter or the signal is exposed, wherein the data transmitter is configured to compensate a data transmitter-side modification of the signal parameter prior to the estimation of the signal parameter or the environmental parameter.

In embodiments, the data transmitter-side modification of the signal parameter (e.g. the offset with which the signal parameter is provided on the data transmitter side) can be known to the data receiver.

In embodiments, the data receiver can be configured to derive the data transmitter-side modification of the signal parameter (e.g. the offset with which the signal parameter is provided on the data transmitter side) from an intrinsic parameter of the communication system of the data receiver or a message transmitted with the signal.

In embodiments, the data receiver can be configured to derive the data transmitter-side modification of the signal parameter (e.g. the offset with which the signal parameter is provided on the data transmitter side) from a cryptographic key or a pair of keys known to the data transmitter and the data receiver.

Further embodiments provide a system having a data transmitter according to one of the embodiments described herein and a data transmitter according to one of the embodiments described herein.

Further embodiments provide a method. The method includes a step of transmitting a signal with transmitting means of the data transmitter, wherein at least one signal parameter of the signal depends on an environmental parameter in an environment of the data transmitter. Further, the method includes a step of shielding the transmitting means or part of the transmitting means from the environmental parameter to reduce a receiver-side reconstructable effect of the environmental parameter on the at least one signal parameter (e.g. to obstruct receiver-side estimation of the environmental parameter based on the at least one signal parameter).

Further embodiments provide a method. The method includes a step of generating a transmitting signal, wherein at least one signal parameter of the transmitting signal depends on an environmental parameter in an environment of the data transmitter, wherein, when generating the transmitting signal, the at least one signal parameter is modified to reduce a receiver-side reconstructable effect of the environmental parameter on the at least one signal parameter (e.g. to obstruct a receiver-side estimation of the environmental parameter based on the at least one signal parameter), wherein the signal parameter directly or a signal derived from a clock signal of a clock generator of the data transmitter, on which the signal or a generation of the signal depends, is modified in order to modify the signal parameter. Further, the method includes a step of transmitting the transmitting signal.

Further embodiments provide a method. The method includes a step of receiving a signal of a data transmitter, wherein the signal or a generation of the signal depends on a clock signal of a clock generator of the data transmitter. Further, the method includes a step of determining a signal parameter of the received signal. Further, the method includes a step of determining, based on the determined signal parameter, an environmental parameter, to which the clock generator of the data transmitter or the signal is exposed. Further, the method includes a step of transmitting the transmitting signal. Further, the method includes a step of compensating a data transmitter-side modification of the signal parameter prior to determining the signal parameter or the environmental parameter.

The present invention is based on the idea of concealing environmental conditions (e.g. environmental parameters) in an environment of a data transmitter that are co-transmitted to a data receiver due to their influence on the characteristics of a transmitted signal (e.g. to obstruct receiver-side estimation of the environmental conditions (e.g. one or several environmental parameters) by evaluating the signal characteristics (e.g. of one or several signal parameters)).

In embodiments, known environmental influences can be compensated on the data transmitter side.

In embodiments (e.g. remaining) environmental influences can be concealed by artificial deviations (e.g. of the signal parameters).

In embodiments, a receiver-side estimation accuracy of specific signal parameters can be reduced by manipulating the signals (e.g. the signal parameters).

### BRIEF DESCRIPTION OF THE DRAWINGS

Embodiments of the present invention will be detailed subsequently referring to the appended drawings, in which:

FIG. 1 shows, in a diagram, a deviation of a high-frequency clock generator from the reference frequency in dependence on the temperature;

FIG. 2 shows, in a diagram, a deviation of a low-frequency clock generator from the reference frequency in dependence on the temperature;

FIG. 3a is a schematic view of a system with a data transmitter and a data receiver as well as a transmission of a signal between the data transmitter and the data receiver, wherein the data receiver can draw conclusions on an environmental parameter in the environment of the data transmitter by evaluating at least one signal parameter of the signal, according to an embodiment of the present invention;

FIG. 3b is a schematic view of a system having a data transmitter and a data receiver as well as a transmission of a signal between the data transmitter and the data receiver with a concealment of at least one signal parameter of the signal according to an embodiment of the present invention;

FIG. 4 is a schematic block diagram of a system having a data transmitter and a data receiver according to an embodiment of the present invention;

FIG. 5 is a schematic block diagram of a system having a data transmitter and a data receiver according to a further embodiment of the present invention;

FIG. 6 is a schematic block diagram of a system having a data transmitter and a data receiver according to a further embodiment of the present invention;

FIG. 7 shows, in a diagram, a temperature profile of the transmitter of the data transmitter when opening and closing a window with and without shielding means for thermal shielding of the transmitter of the data transmitter plotted over time;

FIG. 8 is a schematic block diagram of a system having a data transmitter and a data receiver according to an embodiment of the present invention;

FIG. 9 is a flow diagram of a method for operating a data transmitter according to an embodiment of the present invention;

FIG. 10 is a flow diagram of a method for transmitting a signal according to an embodiment of the present invention; and

FIG. 11 is a flow diagram of a method for determining an environmental parameter in the environment of a data transmitter according to an embodiment of the present invention.

### DETAILED DESCRIPTION OF THE INVENTION

In the following description of the embodiments of the present invention, the same or equal elements are provided with the same reference numbers in the figures, such that the description of the same is interexchangeable.

In typical radio systems, for generating transmitting signals, a reference frequency is needed, from which the respective radio chip or the respective frontend derives the needed clocks. This reference frequency is typically provided by a clock generator, such as oscillating quartz (quartz) [1]. Data transmitters, such as nodes or sensor nodes, typically include two different clock generators. This can, for example, be a high-frequency (HF) clock generator oscillating at a frequency of several MHz and a low-frequency clock generator (LF) normally oscillating at a frequency of 32768 Hz. Normally, the high-frequency clock generator is more accurate (as regards to the deviation from the nominal frequency) and more power-consuming. The low-frequency clock generator is less accurate, but very power-efficient.

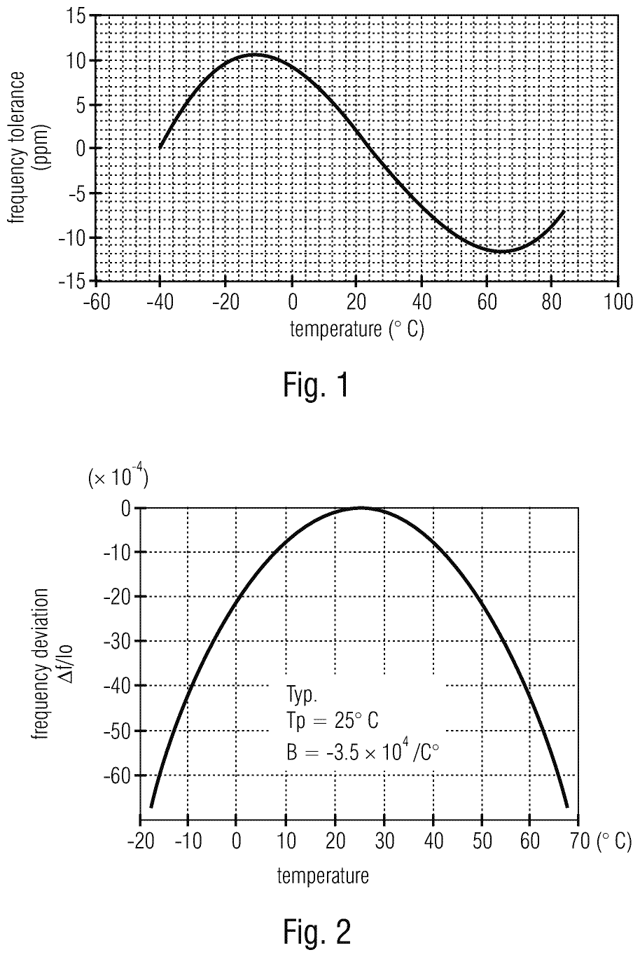

However, the reference frequencies provided by the clock generators (oscillating quartzes) typically depend on environmental parameters. FIG. 1 shows exemplarily the dependency of the reference frequency over temperature for any high-frequency clock generator (frequency stability of a high-frequency oscillating quartz over the ambient temperature [2], while FIG. 2 shows exemplarily the dependency of the reference frequency over temperature for any low-frequency clock generator (frequency stability of a low frequency (LF) 32768 KHz quartz over the temperature [5]). Here, the ordinates each describe the frequency tolerance in ppm and the abscissas each the temperature in ° C.

Apart from the temperature, there are further dependencies of the clock generator (quartz) on at least the following parameters:
humidity
pressure
EM radiation
brightness
vibration/movement

All these parameters have an influence on the reference frequency provided by the clock generator (oscillating quartz). If this reference frequency is used for generating the transmitting signals, these dependencies have a direct effect on the transmitting signal and hence on the transmitting parameters (signal characteristics).

The following transmitting parameters are of specific importance:
transmitting frequency
transmitting time
symbol rate
modulation index (in frequency shift keying methods, such as FSK or GMSK)
Doppler (only at vibration/movement).

Thus, when generating and radiating a radio signal in a transmitter, environmental conditions of the transmitter have an effect on the radiated radio signal. In particular the frequency of oscillators, serving as reference for carrier or modulation frequencies in the transmitter, can be modified by environmental influences. In non-temperature corrected oscillators (quartzes), for example, the frequency correlates with the ambient temperature. Analogous effects can also occur for humidity, electromagnetic radiation, brightness or vibrations. Above that, movements or vibrations of the transmitter and its antenna have an effect on the radiated signal due to Doppler shifts.

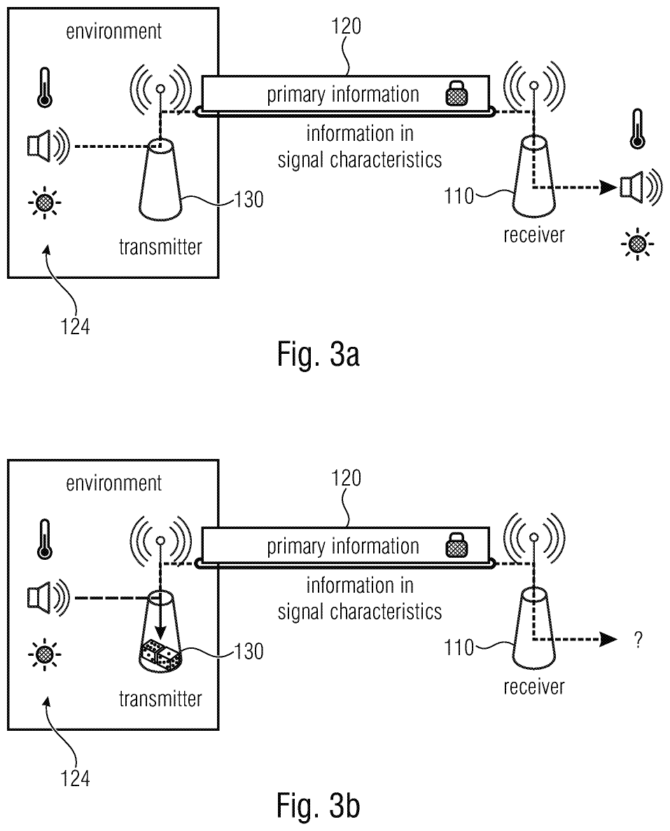

By these characteristics, the radiated signal carries, apart from the primary information, further implicit information on the environmental conditions or characteristics of the transmitter. For illustrating purposes, this phenomenon is shown graphically in FIG. 3.

In detail, FIG. 3a shows a schematic view of a system 100 having a data transmitter 130 and a data receiver 110 as well as a transmission of a signal 120 between the data transmitter 130 and the data receiver 110, wherein the data receiver 110 can draw conclusions on an environmental parameter 124 in the environment of the data transmitter 130 by evaluating at least one signal parameter of the signal 120.

As can be seen in FIG. 3a, the environmental conditions on the side of the data transmitter 130 have an effect on the signal 120 transmitted by the data transmitter 130, such that the signal 120 additionally comprises, apart from primary information, information on the environmental conditions in the signal characteristics. In other words, FIG. 3a shows a radio communication between transmitter 130 and receiver 110, wherein, apart from the transmitted primary information, the information on the signal characteristics is also shown.

If it is possible to determine (e.g. to estimate) the signal characteristics at the receiver 110, conclusions on the environmental conditions at the transmitter 130, at the receiver 110 or in-between can be drawn directly based on the correlation between the signal characteristics and the environmental conditions. However, since the greatest tolerances occur at the transmitter 130, environmental conditions are mostly determined at the transmitter. The temperature can, for example, be determined at the transmitter from a determined frequency offset (deviation from the expected nominal frequency) via the curve shown in FIG. 1.

Modern software defined radio (SDR) receivers allow a very accurate determination of the parameters of a received signal. In that way, for example, a frequency deviation in the range of a few Hz can be detected. This allows the complete or partial reconstruction of environmental conditions or characteristics of the transmitter from the determined signal parameters in the receiver.

Since this meta information is transported by physical characteristics on signal level, the same is not detected by superordinate measures of access protection such as encryption. Therefore, reconstruction can be made by any non-authorized receivers. This represents significant problems with respect to data protection and security for all radio systems having transmitters in non-public areas.

Due to the high density of devices having radio interfaces, extensive target areas arise. Potential scenarios affect both private households as well as industrial or state institutions.

Here, the determination of the environmental conditions does not depend on a specific radio system, any radio system (e.g. WLAN, Bluetooth, radio weather stations, . . . ) can be used for a determination. If several systems exist, a combination can also be used for the determination.

For example, based on a temperature profile over the course of the day it can be determined whether persons stay in a room, a flat or a house. This information can, for example, be used by robbers or can be used for spying activities.

Since apart from the determination of the environmental conditions, frequently, localization of the transmitters, can be performed as well, these are person-related data which are to be pseudonymized according to the new Data Protection Act [4].

Embodiments of the present invention relate to technologies by which the signal characteristics and, hence, environmental conditions can be concealed, such as indicated in FIG. 3b.

In detail, FIG. 3b shows a schematic view of a system having a data transmitter 130 and a data receiver 110, as well as a transmission of a signal 120, between the data transmitter and the data receiver with a concealment of at least one signal parameter of the signal 120 according to an embodiment of the present invention. Caused by concealment of at least one signal parameter of the signal 120, the data receiver 110 can no longer draw conclusions on an environmental parameter 124 in the environment of the data transmitter 130 by evaluating the at least one signal parameter.

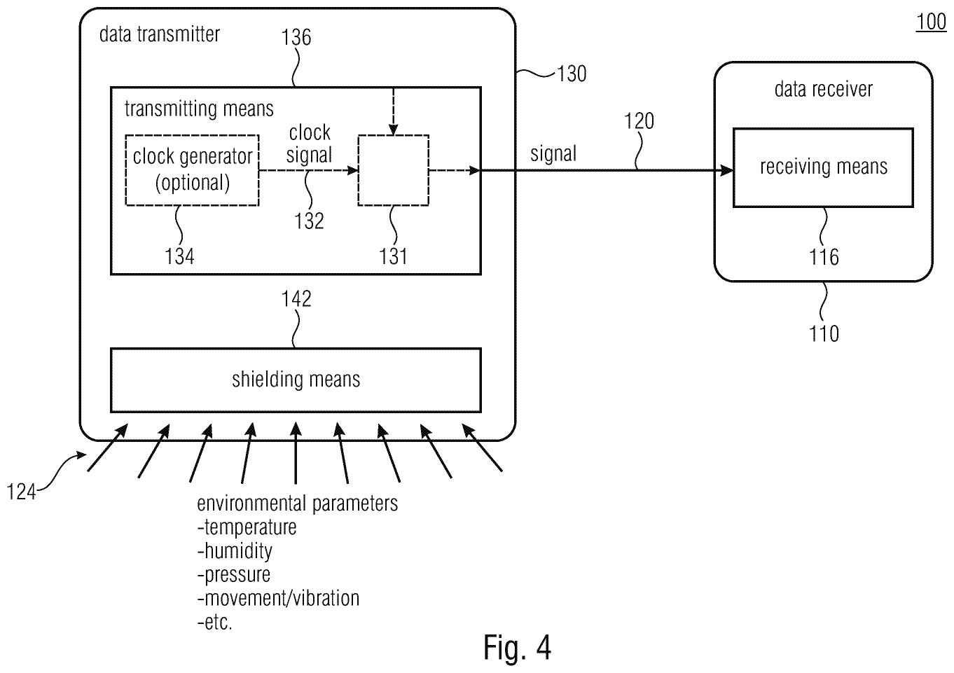

FIG. 4 shows a schematic block diagram of a system 100 having a data transmitter 130 and a data receiver 110 according to an embodiment of the present invention.

The data transmitter 130 includes transmitting means 130 (e.g. transmitter, radio chip/frontend) configured to transmit a signal 120.

The data receiver 110 includes receiving means 116 (e.g. receiver) configured to receive the signal 120.

An environmental parameter 124 acting on the data transmitter 130 can influence the transmitting means 136 or means of the transmitting means 136, such as a clock generator 134 of the transmitting means 136, such that at least one signal parameter of the signal 120 generated by the transmitting means 136 depends on the environmental parameter 124 in the environment of the data transmitter 130.

For example, an environmental parameter 124 (e.g. a temperature or a temperature change) acting on the clock generator 134 of the transmitting means 136 can influence the clock generator 134, and hence at least one clock signal parameter (e.g. clock frequency) of the clock signal 132 provided by the clock generator 134. Since generating the signal 120 transmitted by the data transmitter 130 is based on the clock signal 132 of the clock generator 134, e.g. via a signal processing chain 131 generating the signal 120 based on the clock signal 132, the environmental parameter 124 does not only influence a clock signal parameter (e.g. clock frequency) of the clock signal 132, but also a signal parameter (e.g. a signal characteristic, such as a carrier frequency) of the signal (transmitting signal) 120 generated by the transmitting means 136.

Thus, by evaluating the signal parameter 112 of the received signal 120, the data receiver 110 can draw conclusions on the environmental parameter (e.g. temperature) in the environment of the data transmitter 130 or estimate the same.

Thus, in embodiments, the data transmitter 130 comprises shielding means 142 that is configured to shield the transmitting means 136 or part of the transmitting means 136 (e.g. the clock generator 134 of the transmitting means) from the environmental parameter 124 to reduce a receiver-side reconstructable effect of the environmental parameter 124 on the at least one signal parameter (e.g. to obstruct receiver-side estimation of the environmental parameter based on the at least one signal parameter).

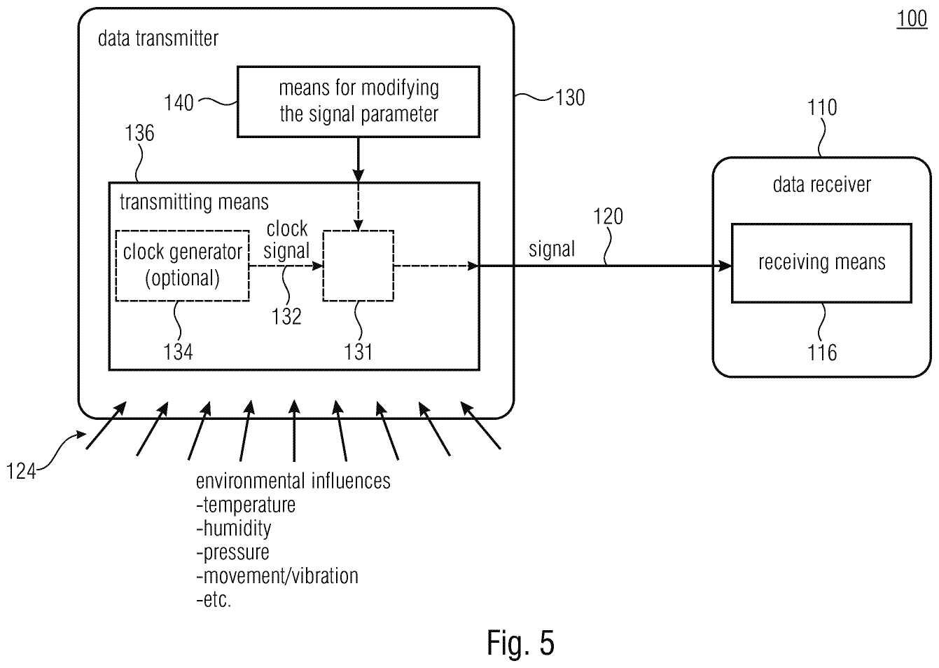

FIG. 5 shows a schematic block diagram of a system 100 having a data transmitter 130 and a data receiver 110 according to an embodiment of the present invention.

Compared to the embodiment shown in FIG. 4, the data transmitter 130 includes, instead of the shielding means 142, means 140 for modifying (e.g. changing) a signal parameter configured to modify at least one signal parameter of the signal to reduce a receiver-side reconstructable effect of the environmental parameter on the at least one signal parameter (e.g. to obstruct a receiver-side estimation of the environmental parameter based on the at least one signal parameter).

Here, the means 140 for modifying the signal parameter can be configured to modify the at least one signal parameter directly (e.g. and not the clock signal 132 provided by the clock generator 134). For example, the means 140 for modifying the signal parameter can be configured to provide the signal parameter (e.g. directly) with an offset in order to modify the signal parameter. For example, the means 140 for modifying the signal parameter can be configured to provide a carrier frequency (=signal parameter) with a carrier frequency offset, a signal phase (=signal parameter) with a signal phase offset, a modulation index (=signal parameter) with a modulation index offset, a symbol rate (=signal parameter) with a symbol rate offset and/or a signal power (=signal parameter) with a signal power offset.

Alternatively (or additionally), the means for modifying the signal parameter can be configured to modify a signal derived from the clock signal 132 of the clock generator 134 on which the signal 120 or a generation of the signal 120 depends in order to modify the at least one signal parameter (e.g. and not the clock signal 132 provided by the clock generator 134). For example, the means 140 for modifying the signal parameter can be configured to modify a signal of a signal processing chain 131 of the transmitting means 136, generating the signal 120 based on the clock signal 132, in order to modify the at least one signal parameter. For example, the signal processing chain 131 downstream of the clock generator 134 can comprise a clock divider/clock multiplier configured to divide/multiply a clock frequency of the clock signal 132 or an adjustable capacitor that is configured to modify the clock signal 132 or a signal derived therefrom in order to modify the at least one signal parameter of the signal 120.

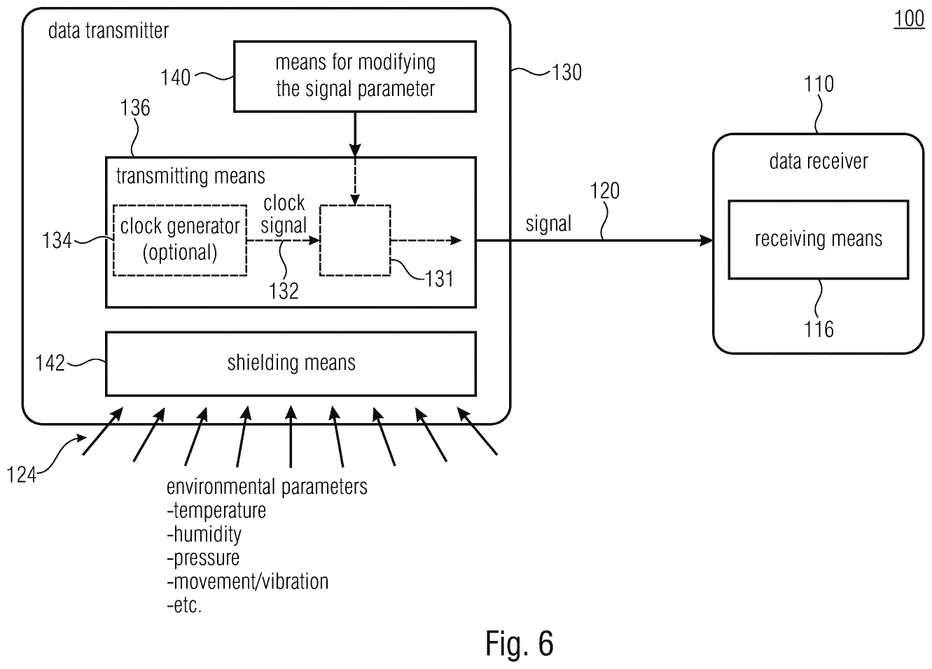

FIG. 6 shows a schematic block diagram of a system 100 having a data transmitter 130 and a data receiver 110 according to an embodiment of the present invention.

Compared to the data transmitters 130 shown in FIGS. 4 and 5, the data transmitter 130 shown in FIG. 6 comprises both the shielding means 142 and the means 140 for modifying the signal parameter.

Here, the shielding means 142 and the means 140 for modifying the signal parameter can supplement each other. For example, the means 140 for modifying the signal parameter can reduce the remaining effects of the environment parameter on one or several signal parameters, which cannot or only be partially compensated or neutralized by the shielding means 142. Here, compensated or neutralized relates to the effects of the environmental parameter on the signal parameter being reduced to the extent that a receiver-side estimation of the environmental parameter based on the signal parameter is not possible or too inaccurate.

In the following, further embodiments of the data transmitter 130 and/or data receiver will be described. The following embodiments can be applied to any of the data transmitters 130 shown in FIGS. 4 to 6.

### 1. Shielding Against Environmental Influences

By shielding the transmitter 136 (or the data transmitter 130) from environmental influences, the effects on the signal characteristics can be reduced or prevented. In the case of the ambient temperature, for example, the inertia against temperature influences can be increased by thermal insulation of the transmitter 136 (or the data transmitter 130).

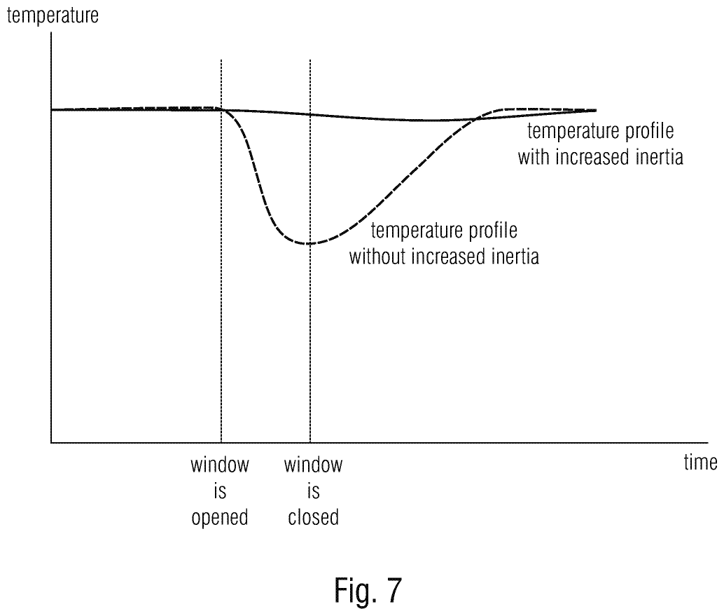

If the temporal resolution is sufficiently reduced thereby, reconstruction of temperature events, such as opening of windows and doors or the presence of persons, can be prevented or at least significantly obstructed as indicated in FIG. 7. This applies analogously to humidity, air pressure, EM radiation and brightness.

In detail, FIG. 7 shows in a diagram a temperature profile of the transmitter 136 of the data transmitter 130 when opening and closing a window with and without shielding means 142 for thermal shielding of the transmitter 136 of the data transmitter plotted over time. Here, the ordinate describes the temperature and the abscissa the time.

By attenuating or decoupling from the vibration source, vibrations can also be reduced or can be shifted to frequency ranges that prevent or obstruct reconstruction in the receiver.

Here, shielding can take place specifically from influences allowing conclusions on events or states which are not to be visible to the outside. Other influences without any use for reconstruction can be maintained as desired concealment.

In embodiments, specific shielding from environmental influences can take place on the data transmitter side in order to reduce or prevent the reconstructable effects on signal characteristics.

In embodiments, a cooling body (for cooling the transmitter 136 or at least part of the transmitter 136) can be attached to the data transmitter side in order to increase thermal stability and/or inertia.

In embodiments, a heating can be attached to the data transmitter side and can be heated in a defined manner prior to transmitting (the transmitter 136 or at least part of the transmitter 136).

In embodiments, the microcontroller (of the data transmitter 136) can be used as heating on the data transmitter side. For example, thermal coupling (of the transmitter 136 or at least part of the transmitter 136) to the microcontroller can be established and, for example, computation-intensive programs can be executed.

In embodiments, programs (executed on the microcontroller) can be timed on the data transmitter side such that prior to transmitting (e.g., constantly) defined times for heating exist. If no needed/useful computations are due, dummy computations can be performed.

In embodiments, heating can be performed (e.g., with the microcontroller or another heating element) for varying amounts of time on the data transmitter side, in dependence on the time of day (e.g., day/night) and/or the season (e.g., summer/winter) etc.

### 2. Adaptation of the Signal Characteristics

If the environmental influences are at least partly known in the data transmitter 130, the same can be specifically compensated. In particular, the current deviation of an oscillator (Quartz) 134 from the set value can be determined via the characteristic curve of the oscillator 134.

For determining the deviation from the set value, for example, one (or several) of the following methods can be used:
Sensor on the transmitter (the sensor can directly determine the environmental conditions),
Signaling by previous transmission from the receiver (transmitter determines the deviation from transmissions of the transmitter and/or other transmitters with correlated environmental influences or receiver has side channel information),
Determining the deviation from the set value from the signal characteristics of a previous transmission of the receiver,
Determining the deviation from the set value via a precise reference (e.g., GPS module),
Determining the deviation from other radio signals with known temperature-stabilized (carrier) frequency (e.g., mobile radio base stations, DCF time signal, etc.), and
Determination by differential consideration of two or more existing quartzes with known characteristic curves.

With the help of the known deviation of the oscillator 134 from the set value, the signal characteristics can be adapted accordingly such that the previously calculated deviations are compensated. For example, the carrier frequency of the transmission signal can be modified and/or the time of emission can be shifted accordingly. Similarly, this can take place for the other stated signal characteristics.

In embodiments, determination of the deviation from the set value can be performed on the data transmitter side and based on these parameters, the environmental influences in the signal characteristics can be corrected specifically.

In embodiments, on the data receiver side, feedback of determined estimated environmental influences on the transmitter side to the transmitter can take place.

In embodiments, the transmitting power can be adjusted on the data transmitter side based on a measured receiving RSSI.

### 3. Readjustment of the Reference Frequency

If the reference frequency in the transmitter 136 can be adapted, for example by a configurable phase-locked loop or by influencing the Quartz 134 via a capacitor or the input voltage, such as in a voltage controlled oscillator, the determined environmental influences can also be compensated directly in the reference frequency. Thus, the reference frequency is shifted such that the same corresponds again to the set value by considering the determined environmental influences.

Determining the environmental influences can here be performed analogously to section 2.

In embodiments, on the data transmitter side, the requested reference frequency can be changed based on the determined environmental influences such that the same corresponds again to the set value.

### 4. Correction of the Derived Frequencies

For signal generation, frequently, frequencies derived from the reference frequency are used. If the same are generated by variable dividers, a known reference frequency error can be corrected by adapting the dividers in the derived frequencies. This can also be combined with a readjustment of the reference frequency for performing, for example, fine correction between discrete frequency stages of a reference frequency.

Here, determining the environmental influences can be performed analogously to section 2.

In embodiments, on the data transmitter side, when generating derived frequencies for signal generation, determined environmental influences can be compensated by adapting the dividers.

Normally, a pierce oscillator is structured around the quartz in order to generate the frequency. In the pierce oscillator, parallel to the quartz, one/two capacitor(s) are switched on, which form the oscillating circuit together with the quartz, and hence determine the resonance frequency, see [5], C1 and C2. The stated capacitors are usually integrated on an IC (integrated circuit) with the microcontroller/radio IC. The capacitors can also be adjusted. Thereby, the desired frequency can be varied. Thereby, the reference frequency responsible for forming carrier frequency/symbol rate/frequency shift changes.

Alternatively, adjustable capacities can be provided on the printed circuit board (e.g., capacitance diode), which can be controlled.

In embodiments, when generating derived frequencies, determined environmental influences can be compensated by adapting adjustable capacitors.

In embodiments, the offsets can be adjusted directly by stating correction values for the carrier frequency and symbol rate by the microcontroller.

### 5. Receiver-Side Determination of Environmental Parameters of a Data Transmitter

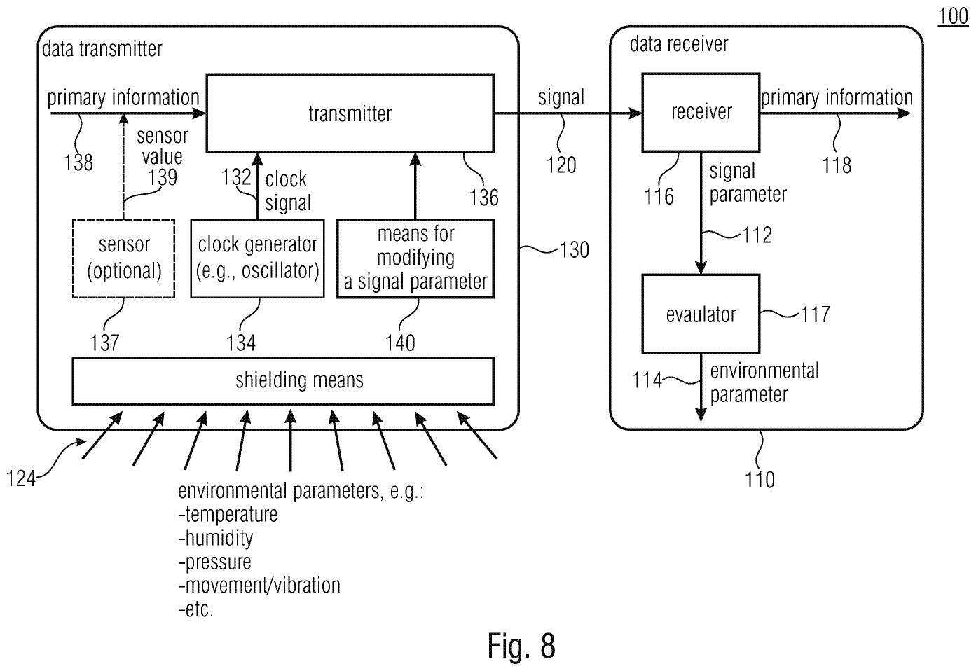

FIG. 8 shows a schematic block diagram of a system 100 having a data transmitter 130 and a data receiver 110 according to an embodiment of the present invention.

The data receiver 110 is configured to receive a signal 120 of the data transmitter 130, wherein the signal 120 depends on a clock signal 132 of a clock generator 134 (e.g., a frequency generator such as an oscillator or quartz) of the data transmitter 130. Further, the data receiver 110 is configured to determine (e.g., evaluate) a signal parameter 112 (e.g., a signal characteristic, such as a carrier frequency or carrier frequency deviation) of the signal 120 and to determine (e.g., to estimate), based on the signal parameter 112, an environmental parameter 114 (e.g., a temperature or temperature change) to which the clock generator 134 of the data transmitter 110 and/or the signal 120 is exposed.

As shown exemplarily in FIG. 8, the data transmitter 130 can comprise a transmitter 136 (radio chip/front end) that is configured to generate the signal 120 (transmitting signal), wherein the signal 120 depends on the clock signal 132 of the clock generator 134. For example, the transmitter 136 can be clocked with the clock signal 132 of the clock generator 134 such that the signal 120 depends on the clock signal 132 of the clock generator 134.

An environmental parameter 124 (e.g., a temperature or temperature change) acting on the clock generator 134 of the data transmitter 130 influences the clock generator 134 and hence at least one signal parameter (e.g., frequency) of the clock signal 132 provided by the clock generator 134. Since the signal 120 transmitted by the data transmitter 130 depends on the clock signal 132, the environmental parameter 124 does not only influence a signal parameter (e.g., frequency) of the clock signal 132, but also a signal parameter (e.g., a signal characteristic, such as carrier frequency) of the signal 120 transmitted by the data transmitter 130.

Thus, by evaluating the signal parameter 112 of the received signal 120, the data receiver 110 can draw conclusions on the environmental parameter (e.g., temperature) in the environment of the data transmitter 130 or estimate the same.

Here, the signal parameter 112 is independent of a modulation content of the signal 120, such as modulated primary information comprised by the signal 120.

For example, the data transmitter 130 (or the transmitter 136 of the data transmitter 130) can be configured to modulate primary information 138 (e.g., an ID (identifier) of the data transmitter 130, a synchronization sequence/pilot sequence, payload data and/or dummy data) such that the signal 120 comprises modulated primary information. However, apart from the modulated primary information, the signal 120 additionally includes information on the environmental parameter 124 (in the environment of the data transmitter 130) in the signal parameter 112, which the data receiver 130 can evaluate to draw conclusions on the environmental parameter 114.

As shown exemplarily in FIG. 8, the data receiver 110 can comprise a receiver 116 that is configured to demodulate the received signal 120 in order to obtain the primary information 118 contained in the signal 120. Further, the data receiver 110 (e.g., the receiver 116 of the data receiver 110) can be configured to determine or evaluate the signal parameter 112 of the received signal 120 in order to obtain the information on the environmental parameter 124 additionally contained in the signal 120. For this, the data receiver 110 can, for example, comprise an evaluator 117 (e.g., a processor) that is configured to determine (e.g., to estimate) the environmental parameter 113 based on the signal parameter 112, for example based on a mapping function mapping the signal parameter 112 on the environmental parameter 114.

In embodiments, the data transmitter 130 (or the transmitter 136 of the data transmitter 130) can be configured to provide, as a signal 120, a digitally modulated signal 120. Here, the data receiver 110 can be configured to determine an analog signal parameter 112 (e.g., an analog signal characteristic, such as a carrier frequency) of the digitally modulated signal 120, and to determine the environmental parameter 114 based on the analog signal parameter 112. Here, the analog signal parameter 112 is independent of a modulation content of the digitally modulated signal 120, such as from digitally modulated primary information comprised by the signal 120.

Thus, in embodiments, it is possible to estimate the environmental parameter in the environment of the data transmitter 130 based on the (analog) signal parameter 112, without having to explicitly transmit the environmental parameter in the modulation content of the signal 120, i.e., in the modulated primary information of the signal 120.

Thus, although primarily completely different payload data or also even only an ID of the data transmitter and/or a synchronization sequence/pilot sequence are transmitted with the signal 120, it is still possible to determine the environmental parameter in the environment of the data transmitter 130 based on the (analog) signal parameter 112.

Determining the environmental parameter in the environment of the data transmitter 130 based on the (analog) signal parameter of the received signal 120 provides a broad spectrum of application options.

In that way, according to embodiments, the data transmitter 130 can comprise a sensor 137 for an environmental parameter 124 as shown exemplarily in FIG. 8. Since the environmental parameter on the side of the data receiver 110 can also be determined based on the (analog) signal parameter 112 of the signal 120, it is no longer needed to transmit the sensor value 139 regularly or with every emission of the signal 120 in the modulated primary information of the signal 120. Rather, it is sufficient to transmit, together with the signal 120 as modulated primary information, a synchronization sequence/pilot sequence and/or an ID of the data transmitter 130 or also only dummy data. Thereby, the amount of data transmitted with the signal 120 can be reduced, whereby also the energy needed for transmission of the signal 120 can be reduced, which is particularly advantageous for battery-operated data transmitters 130. Also, the sensor 137 no longer has to be activated for each emission of the signal 120, which can reduce energy consumption further. Obviously, the sensor value 139 provided by the sensor 137 can additionally be transmitted in an emission or a low number (subset) of emissions of the signal 120 in the modulated primary information and used on the side of the data receiver 110, for example for calibration or initialization. In the same way, it is possible to completely omit the sensor 137 for the environmental parameter on the side of the data transmitter and/or to determine the environmental parameter on the side of the data receiver 110 exclusively based on the determined signal parameter 112 of the received signal 120.

Further, by determining the environmental parameter on the side of the data receiver 110 based on the (analog) signal parameter 112 of the signal 120, it is possible to use a data transmitter 130 comprising a sensor 137 for a first environmental parameter also as a sensor for a second environmental parameter. For example, according to embodiments, the data transmitter 130 can comprise a sensor 137 for a first environmental parameter 124 (e.g., humidity or pressure), wherein the data receiver 110 is configured to determine a second environmental parameter (e.g., temperature) based on the determined signal parameter 112 of the signal 120, wherein the first environmental parameter and the second environmental parameter differ from each other.

Further, by determining the environmental parameter on the side of the data receiver 110 based on the (analog) signal parameter 112 of the received signal 120, it is possible to use a data sensor 130 having no sensor for the environmental parameter as a sensor for an environmental parameter.

Above that, it is possible to use an existing data transmitter 130 as sensor for an environmental parameter (e.g., as temperature sensor) although the data transmitter 130 is actually not intended as sensor for the environmental parameter, for example since the data transmitter 130 has no sensor for the environmental parameter or also since the data transmitter 130 cannot transmit the sensor value.

Optionally, the data transmitter 130 and the data receiver 110 can be configured to transmit or receive data 120 by using the telegram splitting method. Here, a telegram or data packet is split into a plurality of subdata packets (or partial data packets or partial packets) and the subdata packets transmitted from the data transmitter 130 to the data receiver 110 distributed in time according to a hopping pattern and/or distributed in frequency, wherein the data receiver 110 merges (or combines) the subdata packets again in order to obtain the data packet. Here, each of the subdata packets includes only part of the data packet. Further, the data packet can be channel-coded such that not all subdata packets but only part of the subdata packet is needed for error-free decoding of the data packet. Temporal distribution of the plurality of subdata packets can take place according to a time and/or frequency shift pattern.

Since the environmental parameter 124 in the environment of the data transmitter 130 cannot only be determined (e.g., estimated) by the data receiver 110 based on a signal parameter, but theoretically also by any other data receiver which can potentially be an attacker, the data transmitter 130 includes, as already described herein in detail, the means 140 for modifying (e.g., changing or concealing) a signal parameter (see also FIGS. 5 and 6) that is configured to change (e.g., modify, conceal, corrupt or deteriorate) at least one signal parameter (e.g., modulation index, symbol rate, transmission time, carrier frequency, phase) of the signal 120 or a parameter (e.g., clock signal 132) on which the signal parameter of the signal 120 depends and/or the shielding means 142 (see also FIGS. 4 and 6) that is configured to shield the transmitting means 136 or part of the transmitting means 136 (e.g., the clock generator 134 of the transmitting means) from the environmental parameter 124 to reduce a receiver-side reconstructable effect of the environmental parameter 124 on the at least one signal parameter (e.g., for obstructing a receiver-side estimation of the environmental parameter based on the at least one signal parameter).

For the data receiver 110 to be able to determine the environmental parameter 124 in the environment of the data transmitter 130 still based on the at least one signal parameter, the data receiver 110 can be configured, in embodiments, to compensate the data transmitter-side modification (e.g., change) of the signal parameter prior to the estimation of the signal parameter or the environmental parameter.

In embodiments, the data receiver 110 can know the data transmitter-side modification (e.g., change) of the signal parameter (e.g., the offset with which the signal parameter is provided o the data transmitter side).

In embodiments, the data receiver can be configured to derive the data transmitter-side modification (e.g., change) of the signal parameter (e.g., the offset with which the signal parameter is provided on the data transmitter side) from an intrinsic parameter of the communication system of the data transmitter or a message transmitted with the signal.

In embodiments, the data receiver can be configured to derive the data transmitter-side modification (e.g., change) of the signal parameter (e.g., the offset with which the signal parameter is provided on the data transmitter side) from a cryptographic key known to the data transmitter and the data receiver.

In the following, further embodiments of the data receiver 110 and/or data transmitter 130 will be described in more detail.

### 5.1 Deduct Known Influences

Some systems use pseudo-random deviations, for example in the frequency and/or time domain. This would lead to wrong results when estimating the environmental parameters (e.g., temperature estimation). Normally, the pseudo-random deviations follow a known pattern. If this pseudo-random offset determined by scrambling (or the rule how the same is determined) is known to the data receiver 130 (e.g., the base station), this value can be deducted from the receiving parameter before conversion into the environmental parameter takes place.

In embodiments, known artificially added changes of the signal parameters (receiving parameters) can be subtracted, such as a pseudo-random deviation of the transmitting times or the frequency offsets.

Further, intentional concealments as described above can be deducted. Here, the estimation of the receiving parameters functions exactly in the same way as if these concealments were not applied. However, the prerequisite is that the receiver knows the values of the concealment.

In embodiments, hardware-specific errors, which are added, for example by the transmitting hardware of the node, can be subtracted (e.g., deducted).

In embodiments, data transmitter specific (e.g., node specific) data can be stored in the data receiver 110 (e.g., base station).

In embodiments, the intentional changes of the signal parameters can be transformed in the modulated primary information, i.e., in the payload data of the signal 120 or by means of an intrinsic parameter and can be extracted on the side of the data receiver 110 from the modulated primary information (e.g., clear text, CRC, CMAC).

Frequently, a frequency hopping method is used in emissions in order to obtain an improved interference resistance. Thus, the data transmitter 130 transmits on different carrier frequencies. If the data receiver 110 does not know the carrier frequencies of the respective emission in advance, the data receiver 110 can determine, for example, based on an estimation, in what sub-channel the transmission has taken place. If the channel distance between the sub-channels is greater than the maximum quartz defect, this can be obtained by a modulo operation.

For calculating the frequency difference by considering the desired channel, in embodiments, the desired channel can be determined. For this, the frequency can be divided by the channel bandwidth with the modulo operation. A prerequisite for this is that the channel distance is greater than the quartz defect.

For calculating the frequency difference by considering the PLL resolution step, in embodiments, the PLL resolution step can subtracted. For this, the frequency can be divided by the PLL step width with the modulo operation.

For calculating the time difference by considering a time error caused by the transmitter (e.g., transmitting chip) in the data transmitter 130, in embodiments, the time can also be modulo calculated, e.g., on symbol duration or subdata packet duration or telegram duration or timer resolution, wherein the residual of the division yields the desired time error.

For increasing the resolution of the frequency estimation, typically, multi-stage synchronization is used, here, the transmitted data are estimated by means of (partial) decoding. Subsequently, the same can be used for improved frequency estimation by means of re-encoding.

In embodiments, a method with improved frequency estimation accuracy can be used. For example, decoded bits can be encoded again and the phase/frequency (based on the re-encoded bits) can be estimated more accurately.

### 6. Further Embodiments

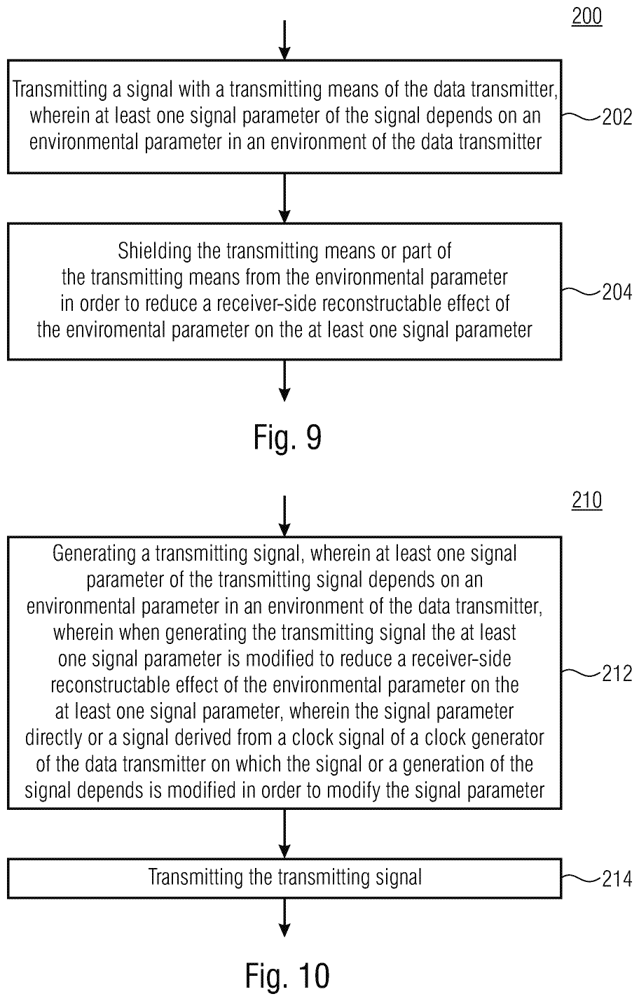

FIG. 9 shows a flow diagram of a method 200 for operating a data transmitter according to an embodiment of the present invention. The method 200 includes a step 202 of transmitting a signal with a transmitting means of the data transmitter, wherein at least one signal parameter of the signal depends on an environmental parameter in an environment of the data transmitter. Further, the method 200 includes a step 204 of shielding the transmitting means or part of the transmitting means from the environmental parameter to reduce a receiver-side reconstructable effect of the environmental parameter on the at least one signal parameter.

FIG. 10 shows a flow diagram of a method 210 for transmitting a signal according to an embodiment of the present invention. The method 210 includes a step 212 of generating a transmitting signal, wherein at least one signal parameter of the transmitting signal depends on an environmental parameter in an environment of the data transmitter, wherein, when generating the transmitting signal, the at least one signal parameter is modified to reduce a receiver-side reconstructable effect of the environmental parameter on the at least one signal parameter, wherein the signal parameter directly or a signal derived from a clock signal of a clock generator of the data transmitter on which the signal or a generation of the signal depends, is modified in order to modify the signal parameter. The method 210 further includes a step 214 of transmitting the transmitting signal.

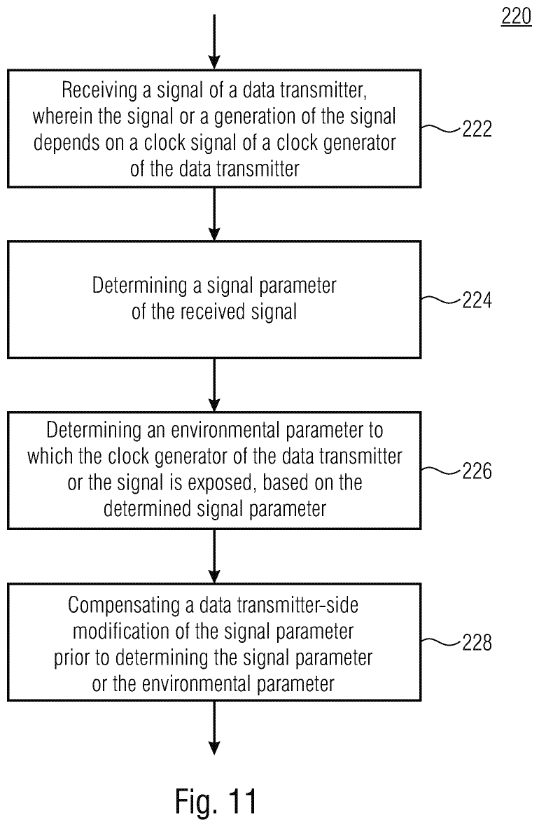

FIG. 11 shows a flow diagram of a method 210 for determining an environmental parameter in the environment of a data transmitter according to an embodiment of the present invention. The method 210 includes a step 212 of receiving a signal of a data transmitter, wherein the signal or a generation of the signal depends on a clock signal of a clock generator (e.g., a frequency generator, such as oscillator or quartz) of the data transmitter. Further, the method 210 includes a step 214 of determining (e.g., estimating) a signal parameter (e.g., a signal characteristic) of the received signal. Further, the method 210 includes a step 216 of determining an environmental parameter (e.g., a temperature or temperature change) to which the clock generator of the data transmitter or the signal is exposed, based on the determined signal parameter. Further, the method 210 includes a step 218 of compensating a data transmitter-side change of the signal parameter prior to determining the signal parameter or the environmental parameter.

As already indicated, in embodiments, data can be transmitted between the data transmitter and the data receiver by using the telegram splitting method. Here, a telegram or data packet is divided into a plurality of subdata packets (or partial data packets or partial packets) and the subdata packets are transmitted discontigously from the data transmitter to the data receiver, e.g., distributed over time and/or in the frequency according to a hopping pattern, wherein the data receiver merges (or combines) the subdata packets again in order to obtain the data packet. Here, each of the subdata packets includes only part of the data packet. Further, the data packet can be channel coded, such that not all subdata packets but only part of the subdata packets is needed for error-free decoding of the data packet. The temporal distribution of the plurality of subdata packets can take place according to a time and/or frequency hopping pattern.

Further embodiments provide a data receiver, wherein the data receiver is configured to receive a signal of a data transmitter, wherein the signal or generation of the signal depends on a clock signal of a clock generator (e.g., a frequency generator, such as oscillator or quartz) of the data transmitter, wherein the data receiver is configured to determine (e.g., evaluate) a signal parameter (e.g., a signal characteristic) of the signal and to determine (e.g., to estimate), based on the signal parameter an environmental parameter (e.g., a temperature or temperature change) to which the clock generator of the data transmitter or the signal is exposed.

In embodiments, the signal parameter can be independent of a modulation content of the signal.

In embodiments, the signal can be a digitally modulated signal, wherein the data receiver can be configured to determine an analog signal parameter (e.g., an analog signal characteristic) of the digitally modulated signal.

For example, the signal parameter can be independent of a modulation content of the digitally modulated signal.

In embodiments, the data receiver can be configured to use known symbols (e.g., pilot symbols) in the signal for determining the signal parameter.

In embodiments, the known symbols can be divided into groups, wherein the groups of symbols can be at different locations of the signal (e.g., at the beginning and the end).

In embodiments, the data receiver can be configured to use at least four known symbols, advantageously 20 known symbols and more advantageously 40 known symbols for determining the signal parameter.

In embodiments, the signal can comprise a plurality of subdata packets, wherein the known symbols are distributed across several subdata packets.

In embodiments, the data receiver can be configured to use no known symbols for determining the signal parameter.

In embodiments, the signal can comprise, apart from modulated primary information (e.g., an ID of the data transmitter, a synchronization sequence, payload data and/or dummy data) information on the environmental parameter in the signal parameter.

In embodiments, the signal can be emitted at specific time intervals (e.g., equal or unequal time intervals), wherein emission of the signal or a real subset of the emissions of the signal can additionally comprise information on the environmental parameter (e.g., a sensorially determined version of the environmental parameter) in the modulated primary information, wherein the data receiver can be configured to calibrate the determination (e.g., estimation or derivation) of the environmental parameter based on the signal parameter based on the information on the environmental parameter included in the modulated primary information.

For example, the data receiver can be configured to receive the signal in a plurality of time periods of the sequence of time periods, wherein the signal received in a first subset of time periods of the sequence of time periods additionally comprises information on the environmental parameter (e.g., a sensorially determined version of the environmental parameter) in the modulated primary information, wherein the data receiver is configured to calibrate the determination (e.g., estimation or derivation) of the environmental parameter based on the signal parameter based on the information on the environmental parameter included in the modulated primary information, wherein the signal received in a second subset of time periods of the sequence of time periods includes no information on the environmental parameter in the modulated primary information, wherein the first subset of time periods and the second subset of time periods are disjoint.

In embodiments, the modulated primary information may not include information on the environmental parameter.

In embodiments, the data receiver can be configured to determine the environmental parameter from the signal parameter based on a mapping function.

In embodiments, the mapping function can be known to the data receiver.

In embodiments, the data receiver can be configured to calibrate the mapping function based on at least one piece of information on the environmental parameter determined by a sensor.

In embodiments, the data receiver can be configured to determine the mapping function based on at least two pieces of information on the environmental parameter determined by a sensor.

In embodiments, the data receiver can be configured to determine the mapping function based on a polynomial approximation in dependency on the at least two pieces of information on the environmental parameter determined by the sensor.

In embodiments, the data receiver can be configured to select the mapping function from a set of mapping functions based on at least one piece of information on the environmental parameter determined by a sensor.

In embodiments, the data receiver can be configured to determine an average value and dispersion across at least two pieces of information on the environmental parameter determined by the sensor, wherein the data receiver can be configured to select the mapping function from the set of mapping functions based on the average value and the dispersion.

In embodiments, the signal can be emitted at specific time intervals (e.g., equal or unequal time intervals), wherein at least one emission of the signal or a real subset of the emissions of the signal (e.g., in the modulated primary information) comprises the at least one piece of information on the environmental parameter determined by the sensor.

In embodiments, the mapping function can be a temperature profile of the clock generator of the data transmitter.

In embodiments, the signal can be emitted at specific time intervals (e.g., equal or unequal time intervals), wherein the data receiver can be configured to determine at least two signal parameters based on at least two emissions of the signal, wherein the data receiver can be configured to determine the environmental parameter based on the at least two signal parameters.

In embodiments, the data receiver can be configured to combine the at least two signal parameters (e.g., by subtraction) in order to obtain a combined signal parameter, wherein the data receiver can be configured to determine the environmental parameter based on the combined signal parameter.

In embodiments, the data receiver can be configured to determine at least two signal parameters (e.g., frequency and modulation error) of the signal, wherein the data receiver can be configured to determine (e.g., to estimate), based on the at least two signal parameters, one environmental parameter (e.g., a temperature or temperature change) each to which the clock generator of the data transmitter or the signal is exposed.

For example, based on the at least two signal parameters, the data receiver can determine equal environmental parameters (e.g., temperatures or temperature differences) or different environmental parameters (e.g., temperature in pressure or a temperature difference and pressure difference).

In embodiments, the data receiver can be configured to combine the determined environmental parameters (e.g., by averaging) in order to obtain a combined environmental parameter.

In embodiments, the signal or a generation of the signal can further depend on a further clock signal of a further clock generator (e.g., frequency generator and timer) of the data transmitter, wherein the data receiver can be configured to determine two signal parameters of the signal and to determine the environmental parameter based on the two signal parameters.

In embodiments, the signal can be emitted at specific time intervals (e.g., equal or unequal time intervals), wherein at least one emission of the signal or a real subset of the emissions of the signal (e.g., in the modulated primary information) comprises information on a deviation of the two clock generators of the data transmitter, wherein the data receiver can be configured to calibrate the determination of the environmental parameter based on the deviation of the two clock generators of the data transmitter.

For example, the deviation of the two clock generators of the data transmitter can indicate the current difference of the frequencies of the two clock generators. For example, the two clock generators (e.g., quartzes) can be measured with respect to one another in order to determine a value (e.g., in ppm, such as 20 ppm), which indicates by how much the two clock generators diverge. The value can be sent as well. The data receiver (e.g., base station) can estimate the time (receiving time) and frequency (receiving frequency) and the information in order to determine/calibrate the quartz temperature profiles of the time quartz or the frequency quartz at the node.

In embodiments, the data receiver can be configured to receive a further signal from a further data transmitter, wherein the further signal or a generation of the further signal depends on a clock signal of a clock generator of the further data transmitter, wherein the data transmitter and the further data transmitter are essentially exposed to the same environmental parameter (e.g., are arranged in the same room), wherein the data receiver can be configured to determine a further signal parameter of the further signal and to determine the environmental parameter based on the signal parameter and the further signal parameter.

In embodiments, the data receiver can be configured to combine the signal parameter and the further signal parameter to obtain a combined signal parameter and to determine the environmental parameter based on the combined signal parameter.

In embodiments, the signal parameter and the further signal parameter can individually allow the determination of a relative environmental parameter (e.g., temperature changes), wherein the data receiver can be configured to determine an absolute environmental parameter based on the signal parameter and the further signal parameter in combination.

In embodiments, the data transmitter and the further data transmitter can belong to different radio systems (e.g., can be data transmitters of different radio systems).

In embodiments, the clock signal of the clock generator can depend on the environmental parameter.

In embodiments, the data receiver can be configured to compensate an age-related influence of the clock generator on the signal parameter.

For example, the data receiver can know the age-related influence of the clock generator on the signal parameter. Further or alternatively, the data receiver can be configured to determine or estimate the age-related influence of the clock generator on the signal parameter, e.g., based on at least two subsequent received signals of the data transmitter.

In embodiments, the data receiver can be configured to compensate an exemplary dispersion-related influence of the clock generator on the signal parameter.

In embodiments, the signal parameter can be
a receiving carrier frequency,
a receiving time,
a receiving symbol rate,
a receiving modulation index,
a Doppler frequency
a signal-to-noise ratio,
a signal power,
a channel phase,
a channel attenuation,
a channel dispersion and/or
a polarization rotation,
   or a change of the same.

In embodiments, the environmental parameter can be
a temperature,
a humidity,
an atmospheric pressure,
an electromagnetic radiation,
a brightness,
a movement and/or
a vibration
   or a change of the same.

Further embodiments provide a system having a data receiver according to one of the embodiments described herein and a data transmitter, wherein the data transmitter can be configured to transmit the signal, wherein the signal or the generation of the signal depends on the clock signal of the clock generator of the data transmitter.

In embodiments, the data transmitter can be configured to transmit the signal at specific time intervals (e.g., equal or unequal time intervals), wherein the data transmitter can be configured to provide at least one emission of the signal or a real subset of the emissions of the signal with information on the environmental parameter determined by a sensor.

Further embodiments provide a method. The method includes a step of receiving a signal of a data transmitter, wherein the signal or a generation of the signal depends on a clock signal of a clock generator (e.g., a frequency generator, such as oscillator or quartz) of the data transmitter. Further, the method includes a step of determining (e.g., estimating) a signal parameter (e.g., a signal characteristic) of the received signal. Further, the method includes a step of determining, based on the determined signal parameter, an environmental parameter (e.g., a temperature or temperature change) to which the clock generator of the data transmitter or the signal is exposed.

In embodiments, the influence of the environment on the clock generator of the data transmitter can be by a factor of at least two or advantageously by a factor of four greater than an influence of the environment on a clock generator of a data receiver that receives the signal of the data transmitter.

In embodiments, the influence of the environment on a clock generator of a data receiver receiving the signal of the data transmitter can be by the factor of at least two or advantageously by the factor of four greater than an influence of the environment on the clock generator of the data transmitter.

Although some aspects have been described in the context of an apparatus, it is obvious that these aspects also represent a description of the corresponding method, such that a block or device of an apparatus also corresponds to a respective method step or a feature of a method step. Analogously, aspects described in the context of a method step also represent a description of a corresponding block or detail or feature of a corresponding apparatus. Some or all of the method steps may be performed by a hardware apparatus (or using a hardware apparatus), such as a microprocessor, a programmable computer or an electronic circuit. In some embodiments, some or several of the most important method steps may be performed by such an apparatus.

Depending on certain implementation requirements, embodiments of the invention can be implemented in hardware or in software. The implementation can be performed using a digital storage medium, for example a floppy disk, a DVD, a Blu-Ray disc, a CD, an ROM, a PROM, an EPROM, an EEPROM or a FLASH memory, a hard drive or another magnetic or optical memory having electronically readable control signals stored thereon, which cooperate or are capable of cooperating with a programmable computer system such that the respective method is performed. Therefore, the digital storage medium may be computer readable.

Some embodiments according to the invention include a data carrier comprising electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer.

The program code may, for example, be stored on a machine readable carrier.

Other embodiments comprise the computer program for performing one of the methods described herein, wherein the computer program is stored on a machine readable carrier.

In other words, an embodiment of the inventive method is, therefore, a computer program comprising a program code for performing one of the methods described herein, when the computer program runs on a computer.

A further embodiment of the inventive method is, therefore, a data carrier (or a digital storage medium or a computer-readable medium) comprising, recorded thereon, the computer program for performing one of the methods described herein. The data carrier, the digital storage medium, or the computer-readable medium are typically tangible or non-volatile.

A further embodiment of the inventive method is, therefore, a data stream or a sequence of signals representing the computer program for performing one of the methods described herein. The data stream or the sequence of signals may, for example, be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment in accordance with the invention includes an apparatus or a system configured to transmit a computer program for performing at least one of the methods described herein to a receiver. The transmission may be electronic or optical, for example. The receiver may be a computer, a mobile device, a memory device or a similar device, for example. The apparatus or the system may include a file server for transmitting the computer program to the receiver, for example.

In some embodiments, a programmable logic device (for example a field programmable gate array, FPGA) may be used to perform some or all of the functionalities of the methods described herein. In some embodiments, a field programmable gate array may cooperate with a microprocessor in order to perform one of the methods described herein. Generally, the methods are performed by any hardware apparatus. This can be a universally applicable hardware, such as a computer processor (CPU) or hardware specific for the method, such as ASIC.

The apparatuses described herein may be implemented, for example, by using a hardware apparatus or by using a computer or by using a combination of a hardware apparatus and a computer.

The apparatuses described herein or any components of the apparatuses described herein may be implemented at least partly in hardware and/or software (computer program).

The methods described herein may be implemented, for example, by using a hardware apparatus or by using a computer or by using a combination of a hardware apparatus and a computer.

The methods described herein or any components of the methods described herein may be performed at least partly by hardware and/or by software (computer program).

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

### REFERENCES

[1] https://de.wikipedia.org/wiki/Schwingquarz
[2] https://www.nxp.com/docs/en/application-note/AN3251.pdf
[3] https://de.wikipedia.org/wiki/Quadraturphasenumtastung#/media/File:QPSK_Gray_Coded.svg
[4] http://eur-lex.europa.eu/legal-content/DE/TXT/PDF/?uri=uriserv:OJ.L_0.2016.119.01.0001.01.DEU
[5] https://de.wikipedia.org/wiki/Pierce-Schaltung

1. Data transmitter, comprising:
transmitter configured to transmit a signal, wherein at least one signal parameter of the signal depends on an environmental parameter in an environment of the data transmitter, and
shielding unit configured to shield the transmitter or part of the transmitter from the environmental parameter to reduce a receiver-side reconstructable effect of the environmental parameter on the at least one signal parameter.

2. Data transmitter according to claim 1,
wherein the transmitter comprises a clock generator,
wherein a clock signal provided by the clock generator depends on the environmental parameter in the environment of the data transmitter,
wherein the signal or a generation of the signal depends on the clock signal of the clock generator,
wherein the shielding unit is configured to shield the transmitter or the clock generator of the transmitter from the environmental parameter.

3. Data transmitter according to claim 1,
wherein the environmental parameter is an ambient temperature,
wherein the shielding unit is configured to thermally shield the transmitter from the environmental temperature.

4. Data transmitter according to claim 1,
wherein the environmental parameter is an ambient temperature,
wherein the shielding unit is configured to increase thermal inertia between the ambient temperature and the transmitter.

5. Data transmitter according to claim 1,
wherein the shielding unit comprises a cooling body thermally coupled to the transmitter.

6. Data transmitter according to claim 1,
wherein the shielding unit is configured to cool the transmitter.

7. Data transmitter according to claim 1,
wherein the shielding unit is configured to heat the transmitter.

8. Data transmitter according to claim 1,
wherein the shielding unit is configured to thermally couple the transmitter or a clock generator of the transmitter to a microcontroller of the data transmitter to influence a temperature of the transmitter or the clock generator.

9. Data transmitter according to claim 8,
wherein the data transmitter is configured to activate the microcontroller at random or pseudo-random times to influence a temperature of the transmitter or the clock generator, and/or
wherein the data transmitter is configured to leave the microcontroller activated for a random or pseudo-random time to influence a temperature of the transmitter or the clock generator.

10. Data transmitter according to claim 1,
wherein the shielding unit is configured to reduce the influence of the environmental parameter on the signal parameter by at least the factor 5.

11. Data transmitter according to claim 1,
wherein the signal parameter of the signal is
a carrier frequency,
a transmitting time,
a symbol rate,
a modulation index or
a signal power
or a change of the same.

12. Data transmitter according to claim 1,
wherein the environmental parameter is
a temperature,
a humidity,
an atmospheric pressure,
an electromagnetic radiation,
a brightness,
a movement and/or
a vibration
or a change of the same.

13. Data transmitter according to claim 1,
wherein the data transmitter comprises a modifier for modifying the signal parameter configured to modify the at least one signal parameter to reduce a receiver-side reconstructable effect of the environmental parameter on the at least one signal parameter,
wherein the modifier for modifying the signal parameter is configured to modify the at least one signal parameter directly or a signal derived from a clock signal of a clock generator of the data transmitter on which the signal or the generation of the signal depends, in order to modify the at least one signal parameter.

14. Data transmitter, comprising:
transmitter configured to transmit a signal, wherein at least one signal parameter of the signal depends on an environmental parameter in an environment of the data transmitter and
a modifier for modifying the signal parameter configured to modify the at least one signal parameter to reduce a receiver-side reconstructable effect of the environmental parameter on the at least one signal parameter,
wherein the modifier for modifying the signal parameter is configured to modify the at least one signal parameter directly or a signal derived from a clock signal of a clock generator of the data transmitter on which the signal or generation of the signal depends, in order to modify the signal parameter.

15. Data transmitter according to claim 14,
wherein the modifier for modifying the signal parameter is configured to modify the signal parameter based on a deviation of the signal parameter from a set value.

16. Data transmitter according to claim 14,
wherein a clock signal provided by the clock generator depends on the environmental parameter in the environment of the data transmitter,
wherein the signal or a generation of the signal depends on the clock signal of the clock generator.

17. Data transmitter according to claim 16,
wherein the modifier for modifying the signal parameter is configured to determine a deviation of a clock signal parameter of the clock signal from a set value,
wherein the modifier for modifying the signal parameter is configured to modify the signal parameter of the signal based on the determined deviation of the clock signal parameter.

18. Data transmitter according to claim 14,
wherein the modifier for modifying the signal parameter is configured to modify the signal parameter of the signal in dependence on the environmental parameter in the environment of the data transmitter.

19. Data transmitter according to claim 18,
wherein the data transmitter is configured to determine the environmental parameter in the environment of the data transmitter.

20. Data transmitter according to claim 18,
wherein the data transmitter is configured to receive a signal from a different data transmitter,
wherein the received signal comprises information on the environmental parameter in the environment of the data transmitter or wherein the data transmitter is configured to estimate the environmental parameter in the environment of the data transmitter based on a signal parameter of the received signal.

21. Data transmitter according to claim 14,
wherein the modifier for modifying the signal parameter is configured to change a clock divider of the clock signal used for generating the signal based on the environmental parameter in the environment of the data transmitter in order to modify the signal parameter of the signal, wherein the clock divider is not part of the clock generator.

22. Data transmitter according to claim 14,
wherein the modifier for modifying the signal parameter is configured to adjust an adjustable capacitor used for generating the signal based on the environmental parameter in the environment of the data transmitter to modify the signal parameter of the signal, wherein the capacitor is not part of the clock generator.

23. Data transmitter according to claim 14,
wherein the modifier for modifying the signal parameter is configured to output correction values for the signal parameter to the transmitter to modify the signal parameter of the signal.

24. Data transmitter according to claim 14,
wherein the signal parameter of the signal is
a carrier frequency,
a transmitting time,
a symbol rate,
a modulation index or
a signal power
or a change of the same.

25. Data transmitter according to claim 14,
wherein the environmental parameter is
a temperature,
a humidity,
an atmospheric pressure,
an electromagnetic radiation,
a brightness,
a movement and/or
a vibration
or a change of the same.

26. Data receiver,
wherein the data receiver is configured to receive a signal of a data transmitter, wherein the signal or a generation of the signal depends on a clock signal of a clock generator of the data transmitter,
wherein the data receiver is configured to determine a signal parameter of the signal and to determine, based on the signal parameter, an environmental parameter to which the clock generator of the data transmitter or the signal is exposed,
wherein the data transmitter is configured to compensate a data transmitter-side modification of the signal parameter prior to the estimation of the signal parameter or the environmental parameter.

27. Data receiver according to claim 26,
wherein the data receiver knows the data transmitter-side modification of the signal parameter.

28. Data receiver according to claim 26,
wherein the data receiver is configured to derive the data transmitter-side modification of the signal parameter from an intrinsic parameter of the communication system of the data receiver or a message transmitted with the signal.

29. Data receiver according to claim 26,
wherein the data receiver is configured to derive the data transmitter-side modification of the signal parameter from a cryptographic key or pair of keys known to the data transmitter and the data receiver.

30. System, comprising:
a data transmitter, comprising:
transmitter configured to transmit a signal, wherein at least one signal parameter of the signal depends on an environmental parameter in an environment of the data transmitter, and
shielding unit configured to shield the transmitter or part of the transmitter from the environmental parameter to reduce a receiver-side reconstructable effect of the environmental parameter on the at least one signal parameter, and
a data transmitter, comprising:
a transmitter configured to transmit a signal, wherein at least one signal parameter of the signal depends on an environmental parameter in an environment of the data transmitter and
a modifier for modifying the signal parameter configured to modify the at least one signal parameter to reduce a receiver-side reconstructable effect of the environmental parameter on the at least one signal parameter,
wherein the modifier for modifying the signal parameter is configured to modify the at least one signal parameter directly or a signal derived from a clock signal of a clock generator of the data transmitter on which the signal or generation of the signal depends, in order to modify the signal parameter, and
a data receiver according to claim 26.

31. Method, comprising:
transmitting a signal with transmitter of the data transmitter, wherein at least one signal parameter of the signal depends on an environmental parameter in an environment of the data transmitter,
shielding the transmitter or part of the transmitter from the environmental parameter to reduce a receiver-side reconstructable effect of the environmental parameter on the at least one signal parameter.

32. Method for operating a data transmitter, comprising:
generating a transmitting signal, wherein at least one signal parameter of the transmitting signal depends on an environmental parameter in an environment of the data transmitter, wherein, when generating the transmitting signal, the at least one signal parameter is modified to reduce a receiver-side reconstructable effect of the environmental parameter on the at least one signal parameter, wherein the signal parameter directly or a signal derived from a clock signal of a clock generator of the data transmitter on which the signal or generation of the signal depends is modified in order to modify the signal parameter and
transmitting the transmitting signal.

33. Method, comprising:
receiving a signal of a data transmitter, wherein the signal or a generation of the signal depends on a clock signal of a clock generator of the data transmitter,
determining a signal parameter of the received signal,
determining, based on the determined signal parameter, an environmental parameter to which the clock generator of the data transmitter or the signal is exposed, and
compensating a data transmitter-side modification of the signal parameter prior to determining the signal parameter or the environmental parameter.

34. A non-transitory digital storage medium having a computer program stored thereon to perform the method comprising:
transmitting a signal with transmitter of the data transmitter, wherein at least one signal parameter of the signal depends on an environmental parameter in an environment of the data transmitter,
shielding the transmitter or part of the transmitter from the environmental parameter to reduce a receiver-side reconstructable effect of the environmental parameter on the at least one signal parameter,
when said computer program is run by a computer.

35. A non-transitory digital storage medium having a computer program stored thereon to perform the method for operating a data transmitter, the method comprising:
generating a transmitting signal, wherein at least one signal parameter of the transmitting signal depends on an environmental parameter in an environment of the data transmitter, wherein, when generating the transmitting signal, the at least one signal parameter is modified to reduce a receiver-side reconstructable effect of the environmental parameter on the at least one signal parameter, wherein the signal parameter directly or a signal derived from a clock signal of a clock generator of the data transmitter on which the signal or generation of the signal depends is modified in order to modify the signal parameter and
transmitting the transmitting signal,
when said computer program is run by a computer.

36. A non-transitory digital storage medium having a computer program stored thereon to perform the method comprising:
receiving a signal of a data transmitter, wherein the signal or a generation of the signal depends on a clock signal of a clock generator of the data transmitter,
determining a signal parameter of the received signal,
determining, based on the determined signal parameter, an environmental parameter to which the clock generator of the data transmitter or the signal is exposed, and
compensating a data transmitter-side modification of the signal parameter prior to determining the signal parameter or the environmental parameter,
when said computer program is run by a computer.
